(19) United States
(12) Patent Application Publication
(10) Pub. No.: US 2026/0114168 A1
(43) Pub. Date: Apr. 23, 2026

(54) Display Apparatus

(71) Applicant: LG Display Co., Ltd., Seoul (KR)

(72) Inventor: Hyunjik Bae, Daegu (KR)

(21) Appl. No.: 19/232,429

(22) Filed: Jun. 9, 2025

(30) Foreign Application Priority Data
Oct. 21, 2024 (KR) 10-2024-0144214

(51) Int. Cl. H10K 59/80; H10K 59/122; H10K 59/40

(52) U.S. Cl. CPC H10K 59/8792; H10K 59/122; H10K 59/40; H10K 59/879

(57) ABSTRACT

Provided is a display apparatus. The display apparatus comprises a substrate including a sub pixel, a first over coating layer which is disposed on the substrate and includes a base portion and a protruding portion disposed on the base portion, a light emitting diode which is disposed in the sub pixel and covers a top surface of the base portion and a side surface of the protruding portion, a first optical pattern disposed on the light emitting diode, and a second optical pattern which is disposed on the first optical pattern and overlaps the first optical pattern, the first optical pattern and the second optical pattern protruding in different directions, wherein the side surface of the protruding portion forms an inclined surface with respect to the top surface of the base portion.

### CROSS-REFERENCE TO RELATED APPLICATION

This application claims the priority of Republic of Korean Patent Application No. 10-2024-0144214 filed on Oct. 21, 2024, which is hereby incorporated by reference in its entirety.

### BACKGROUND

### Field

The present disclosure relates to a display apparatus, and more particularly, to a display apparatus with an improved viewing angle.

### Description of the Related Art

Recently, display apparatus, which visually display electrical information signals, are being rapidly developed in accordance with the full-fledged entry into the information era. Various studies are being continuously conducted to develop a variety of display apparatus which are thin and lightweight, consume low power, and have improved performance.

As the representative display apparatus, there are a liquid crystal display (LCD) device, an electrowetting display (EWD) device, an organic light-emitting display (OLED) device, and the like.

Among the display apparatus, the display apparatus including the organic light-emitting display apparatus refers to a display apparatus that autonomously emits light. Unlike a liquid crystal display apparatus, the electroluminescent display apparatus does not require a separate light source and thus may be manufactured as a lightweight, thin display apparatus. In addition, the electroluminescent display apparatus is advantageous in terms of power consumption because the electroluminescent display apparatus operates at a low voltage. Further, the electroluminescent display apparatus is expected to be adopted in various fields because the electroluminescent display apparatus is also excellent in implementation of colors, response speeds, viewing angles, and contrast ratios (CRs).

### SUMMARY

An object to be achieved by the present disclosure is to provide a display apparatus in which a viewing angle is improved by placing a plurality of optical patterns on an encapsulation unit of a display panel.

Another object to be achieved by the present disclosure is to provide a display apparatus in which a touch sensing unit is used as an optical pattern to reduce an optical pattern formation process.

Still another object to be achieved by the present disclosure is to provide a display apparatus in which a front luminance and a side luminance are simultaneously improved.

Still another object to be achieved by the present disclosure is to provide a display apparatus in which a three-dimensional (3D) crosstalk is improved.

Still another object to be achieved by the present disclosure is to provide a display apparatus with a reduced thickness by forming a plurality of optical patterns together with a touch sensing unit.

Objects of the present disclosure are not limited to the above-mentioned objects, and other objects, which are not mentioned above, can be clearly understood by those skilled in the art from the following descriptions.

According to an embodiment of the present disclosure, there is provided a display apparatus. The display apparatus comprises a substrate including a sub pixel, a first over coating layer which is disposed on the substrate and includes a base portion and a protruding portion disposed on the base portion, a light emitting diode which is disposed in the sub pixel and covers a top surface of the base portion and a side surface of the protruding portion, a first optical pattern disposed on the light emitting diode, and a second optical pattern which is disposed on the first optical pattern and overlaps the first optical pattern, the first optical pattern and the second optical pattern protruding in different directions, wherein the side surface of the protruding portion forms an inclined surface with respect to the top surface of the base portion.

According to another embodiment of the present disclosure, there is provided a display apparatus. The display apparatus comprises a substrate including a sub pixel, an over coating layer which is disposed on the substrate and includes a base portion and a protruding portion disposed on the base portion, a light emitting diode which is disposed in the sub pixel and covers a top surface of the base portion and a side surface of the protruding portion, a concave lens disposed above the light emitting diode, and a convex patterns which overlaps the concave lens on the concave lens.

Other detailed matters of the exemplary embodiments are included in the detailed description and the drawings.

According to the present disclosure, a plurality of optical patterns is disposed on the display panel to improve a front luminance and a side luminance so that the display apparatus may be driven at low power.

According to the present disclosure, a left-eye image is suppressed from entering a right-eye image to suppress the crosstalk.

According to the present disclosure, the touch sensing unit and the optical pattern are formed together to optimize the process and reduce a manufacturing process and a manufacturing cost of the display apparatus.

According to the present disclosure, a plurality of optical patterns is disposed in a touch sensing unit to reduce a thickness of the display apparatus.

The effects of the present disclosure are not limited to the aforementioned effects, and other effects, which are not mentioned above, will be apparently understood to a person having ordinary skill in the art from the following description.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a functional block diagram of a display apparatus according to an exemplary embodiment of the present disclosure;

FIG. 2 is a plan view of a pixel of a display apparatus according to an exemplary embodiment of the present disclosure;

FIG. 3 is a circuit diagram of a sub pixel of a display apparatus according to an exemplary embodiment of the present disclosure;

FIG. 4 is a plan view of a sub pixel of a display apparatus according to an exemplary embodiment of the present disclosure;

FIG. 5 is a cross-sectional view taken along the line A-A′ of FIG. 2 according to an exemplary embodiment of the present disclosure; and

FIG. 6 is a cross-sectional view of a sub pixel of a display apparatus according to another exemplary embodiment of the present disclosure.

### DETAILED DESCRIPTION

Most of the terms used herein are general terms that have been widely used in the technical art to which the present disclosure pertains. However, some of the terms used herein may be created reflecting intentions of technicians in this art, precedents, or new technologies. Also, some of the terms used herein may be arbitrarily chosen by the present applicant. In this case, these terms are defined in detail below. Accordingly, the specific terms used herein should be understood based on the unique meanings thereof and the whole context of the present disclosure.

In the disclosure, ‘include’ or ‘comprise’ should be interpreted as that other components may further be included, not excluded, unless otherwise specified.

The expression “at least one of a, b, and c” described throughout the specification may include “a alone,” “b alone,” “c alone,” “a and b,” “a and c,” “b and c,” or “all of a, b, and c.” Advantages and features of the present disclosure, and methods for accomplishing the same will be more clearly understood from embodiments described below with reference to the accompanying drawings.

The shapes, areas, ratios, angles, numbers, and the like illustrated in the accompanying drawings for describing exemplary embodiments of the present disclosure are merely examples, and the present disclosure is not limited thereto. Further, in the following description, a detailed explanation of known related technologies may be omitted to avoid unnecessarily obscuring the subject matter of the present disclosure.

The terms such as “including,” “having,” and “comprising” used herein are generally intended to allow other components to be added unless the terms are used with the term “only”. Any references to singular may include plural unless expressly stated otherwise. Components are interpreted to include an ordinary error range even if not expressly stated.

For example, when the position relation between two parts is described using the terms such as “on”, “above”, “below”, and “next”, one or more parts may be located between the two parts. When an element or layer is referred to as being “on” another element or layer, it may be directly on the other element or layer, or intervening elements or layers may be present.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Since an area, a size and a thickness of each component illustrated in the drawings are represented for convenience in explanation, the present disclosure is not necessarily limited to the illustrated size and thickness of each component.

The features of various embodiments of the present disclosure can be partially or entirely bonded to or combined with each other and can be interlocked and operated in technically various ways, and the embodiments can be carried out independently of or in association with each other.

In addition, the terms described below are terms defined in consideration of functions in the implementation of the present disclosure, and may vary depending on the intention or custom of a user or operator. Therefore, the definition thereof should be made based on the contents throughout this specification.

Transistors constituting a pixel circuit of the present disclosure may include at least one of oxide TFT (oxide thin film transistor; oxide TFT), amorphous silicon TFT (a-Si TFT), and low temperature poly silicon (LTPS) TFT.

Expressions such as ‘first’, ‘second’, and ‘third’ are terms used to distinguish configurations for each embodiment, and the embodiments are not limited to these terms. Therefore, it should be noted that the same terms may refer to different configurations depending on the embodiments.

Hereinafter, embodiments of the present disclosure will be described with reference to the drawings.

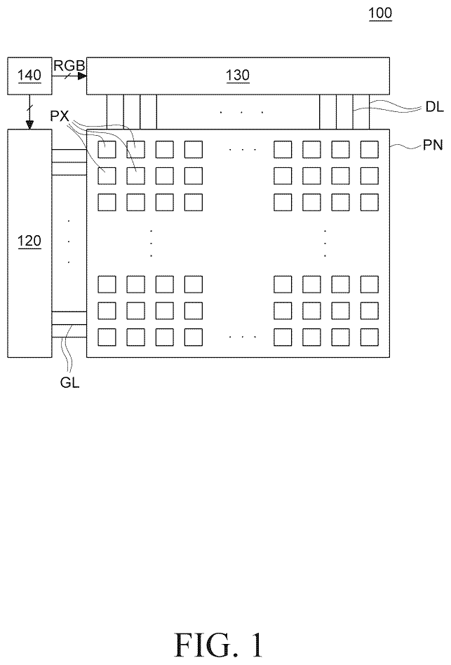

FIG. 1 is a functional block diagram of a display apparatus according to an exemplary embodiment of the present disclosure.

The display apparatus 100 according to the exemplary embodiment of the present disclosure may be applied with the electroluminescent display apparatus. The electroluminescent display apparatus may use an organic light emitting diode (OLED) display apparatus, a quantum dot light emitting diode display apparatus, or an inorganic light emitting diode display apparatus.

Referring to FIG. 1, the display apparatus 100 may include a display panel PN, a data driving circuit 130, a gate driving circuit 120, and a timing controller 140.

The display panel PN may generate images to be provided to the user. For example, the display panel PN may generate and display images to be provided to the user through a pixel PX in which a plurality of pixel circuits is disposed.

The data driving circuit 130, the gate driving circuit 120, and the timing controller 140 may provide signals for operations of the pixels PX through signal lines. The signal lines may include data lines DL and gate lines GL, for example.

The data lines DL are disposed in a column direction and may include a plurality of wiring lines connected to pixels PX disposed in one column direction and the gate lines GL are disposed in a row direction and may include a plurality of wiring lines connected to pixels PX disposed in one row direction.

In some cases, the display apparatus 100 may further include a power unit (e.g., a circuit). In this case, a signal for an operation of the pixel PX may be supplied through the power line which connects the power unit and the display panel PN. According to the exemplary embodiment, the power unit may supply a power to the data driving circuit 130 and the gate driving circuit 120. The data driving circuit 130 and the gate driving circuit 120 may be driven based on the power supplied from the power unit.

For example, the data driving circuit 130 may apply a data signal to each pixel PX through the data lines DL. The gate driving circuit 120 may apply a gate signal to each pixel PX through the gate lines GL. The power unit may supply a power voltage to each pixel PX through the power voltage supply lines.

The timing controller 140 may control the data driving circuit 130 and the gate driving circuit 120. For example, the timing controller 140 rearranges digital video data RGB input from the outside in accordance with a resolution of the display panel PN to supply the digital video data RGB to the data driving circuit 130.

The data driving circuit 130 converts digital video data input from the timing controller 140 into an analog data voltage based on the data control signal to supply the converted analog data voltage to the plurality of data lines DL.

The gate driving circuit 120 may generate a scan signal and an emission signal (or an emission control signal) based on the gate control signal. The gate driving circuit 120 may include a scan driver and an emission signal driver. The scan driver generates a scan signal in a row sequential manner to drive at least one scan line connected to each pixel row to supply the scan signal to the scan lines. The emission signal driver generates an emission signal in a row sequential manner to drive at least one emission signal line connected to each pixel row to supply the emission signal to the emission signal lines.

According to the exemplary embodiment, the gate driving circuit 120 may be disposed in the display panel PN in a gate-driver in panel (GIP) manner. For example, the gate driving circuit 120 is divided into a plurality of circuits to be disposed on at least two side surfaces of the display panel PN.

The display panel PN may include an active area and a non-active area which encloses the active area.

The active area of the display panel PN may include a plurality of pixels PX disposed in a row direction and a column direction. The pixel PX may be disposed in an intersecting area of a plurality of data lines DL and a plurality of gate lines GL.

One pixel PX may include a plurality of sub pixels which emits different color light. For example, the pixel PX uses a plurality of sub pixels to implement blue light, red light, and green light. However, this is not limited thereto and in some cases, the pixel PX may further include a sub pixel for further implementing a specific color (for example, white).

The non-active area may be disposed along the circumference of the active area. Various components for driving a plurality of sub pixel circuits disposed in the pixel PX may be disposed in the non-active area. For example, at least a part of the gate driving circuit 120 may be disposed in the non-active area. The non-active area may be referred to as a bezel area.

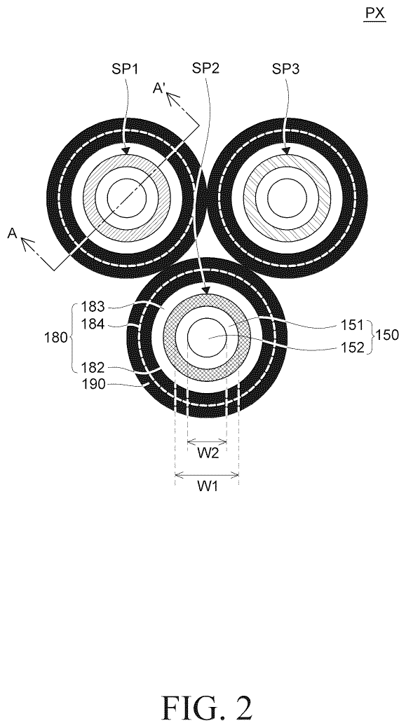

Hereinafter, the plurality of pixels PX will be described in detail with reference to FIG. 2.

FIG. 2 is a plan view of a pixel of a display apparatus according to an exemplary embodiment of the present disclosure.

Referring to FIG. 2, the pixel PX may include a first sub pixel SP1, a second sub pixel SP2, and a third sub pixel SP3. For example, the first sub pixel SP1 may be a red sub pixel, the second sub pixel SP2 may be a green sub pixel, and the third sub pixel SP3 may be a blue sub pixel, but it is not limited thereto.

The first sub pixel SP1, the second sub pixel SP2, and the third sub pixel SP3 may have the same shape. For example, the first sub pixel SP1, the second sub pixel SP2, and the third sub pixel SP3 may have the same area. However, the first sub pixel SP1, the second sub pixel SP2, and the third sub pixel SP3 may have a different shape without being limited thereto. For example, in consideration of a lifespan and a luminous efficiency of the light emitting diode, the first sub pixel SP1, the second sub pixel SP2, and the third sub pixel SP3 may have different areas.

In the meantime, even though in FIG. 2, it is illustrated that the first sub pixel SP1, the second sub pixel SP2, and the third sub pixel SP3 have a circular planar shape, a planar shape of the first sub pixel SP1, the second sub pixel SP2, and the third sub pixel SP3 may not be limited thereto.

A light shielding pattern 190 is disposed in each of the first sub pixel SP1, the second sub pixel SP2, and the third sub pixel SP3.

The light shielding pattern 190 may be disposed so as not to overlap the optical pattern 150. For example, the optical pattern 150 may be disposed in a center portion of each of the first sub pixel SP1, the second sub pixel SP2, and the third sub pixel SP3 and the light shielding pattern 190 may be disposed in an edge of each of the first sub pixel SP1, the second sub pixel SP2, and the third sub pixel SP3.

A touch sensing unit 180 is disposed in each of the first sub pixel SP1, the second sub pixel SP2, and the third sub pixel SP3.

The touch sensing unit 180 includes an insulating layer such as an inorganic insulating layer, an organic layer 183 and an organic insulating layer, and a metal layer such as a touch electrode 182 and a bridge electrode 184. For example, the touch electrode 182 and the bridge electrode 184 may be disposed to be spaced apart from each other with the organic layer 183 therebetween.

The touch electrode 182 and the bridge electrode 184 may be disposed so as not to overlap (e.g., non-overlapping) the optical pattern 150. For example, the optical pattern 150 may be disposed in a center portion of each of the first sub pixel SP1, the second sub pixel SP2, and the third sub pixel SP3 and the touch electrode 182 and the bridge electrode 184 may be disposed in an edge of each of the first sub pixel SP1, the second sub pixel SP2, and the third sub pixel SP3.

A plurality of optical patterns 150 are disposed in each of the first sub pixel SP1, the second sub pixel SP2, and the third sub pixel SP3. The plurality of optical patterns 150 may be disposed so as not to overlap (e.g., non-overlapping) the touch electrode 182 and the bridge electrode 184 of the touch sensing unit 180 and the light shielding pattern 190.

The plurality of optical patterns 150 is disposed on the plurality of light emitting diodes disposed in each of the first sub pixel SP1, the second sub pixel SP2, and the third sub pixel SP3 to transmit light emitted from each of the first sub pixel SP1, the second sub pixel SP2, and the third sub pixel SP3. At this time, the plurality of optical patterns 150 may restrict or change a traveling direction of light emitted from each of the first sub pixel SP1, the second sub pixel SP2, and the third sub pixel SP3.

The plurality of optical patterns 150 may have a shape of restricting or changing a traveling direction of light emitted from each of the first sub pixel SP1, the second sub pixel SP2, and the third sub pixel SP3. For example, the plurality of optical patterns 150 may have a shape protruding in one direction.

The plurality of optical patterns 150 may have a shape corresponding to a shape of each of the first sub pixel SP1, the second sub pixel SP2, and the third sub pixel SP3. For example, when each of the first sub pixel SP1, the second sub pixel SP2, and the third sub pixel SP3 has a circular planar shape, each of the plurality of optical patterns 150 may have a circular planar shape, but it is not limited thereto.

The plurality of optical patterns 150 may include a first optical pattern 151 and a second optical pattern 152 according to one embodiment.

The first optical pattern 151 and the second optical pattern 152 may have different areas. For example, an area of the first optical pattern 151 which overlaps the substrate may be larger than an area of the second optical pattern 152 which overlaps the substrate. Referring to FIG. 2, a width W1 of the first optical pattern 151 may be larger than a width W2 of the second optical pattern 152.

The first optical pattern 151 and the second optical pattern 152 may overlap each other. Accordingly, if an area of the first optical pattern 151 is larger than an area of the second optical pattern 152, a part of the first optical pattern 151 may be exposed from the second optical pattern 152.

A center of the first optical pattern 151 and a center of the second optical pattern 152 may correspond to each other. Accordingly, a center portion of the first optical pattern 151 may overlap with the second optical pattern 152 and an edge of the first optical pattern 151 may be exposed from the second optical pattern 152.

The first optical pattern 151 and the second optical pattern 152 may be disposed so as to correspond to a center portion of each of the first sub pixel SP1, the second sub pixel SP2, and the third sub pixel SP3. Accordingly, the center portion of each of the first sub pixel SP1, the second sub pixel SP2, and the third sub pixel SP3 may overlap both the first optical pattern 151 and the second optical pattern 152. The edge of each of the first sub pixel SP1, the second sub pixel SP2, and the third sub pixel SP3 may overlap the first optical pattern 151, but may not overlap the second optical pattern 152.

Accordingly, light traveling toward the center portion of the first optical pattern 151, among light emitted from the first sub pixel SP1, the second sub pixel SP2, and the third sub pixel SP3, may transmit the second optical pattern 152 together with the first optical pattern 151 to travel to the outside of the display apparatus 100. Light traveling toward the edge of the first optical pattern 151 may transmit only the first optical pattern 151 to travel to the outside of the display apparatus 100.

One surface of the first optical pattern 151 may be formed to have a planar shape and the other surface of the first optical pattern 151 which is opposite to one surface of the first optical pattern 151 may be formed to have a non-planar shape. One surface of the second optical pattern 152 may be formed to have a planar shape and the other surface of the second optical pattern 152 which is opposite to one surface of the second optical pattern 152 may be formed to have a non-planar shape. For example, the other surface of each of the first optical pattern 151 and the second optical pattern 152 may have a convex shape so that the first optical pattern 151 and the second optical pattern 152 may have a hemispherical shape, but are not limited thereto.

In the meantime, the first optical pattern 151 and the second optical pattern 152 may protrude in different directions. For example, the first optical pattern 151 may protrude to a direction in which a bottom surface of the display apparatus 100 is located and the second optical pattern 152 may protrude to a direction in which a top surface of the display apparatus 100 is located.

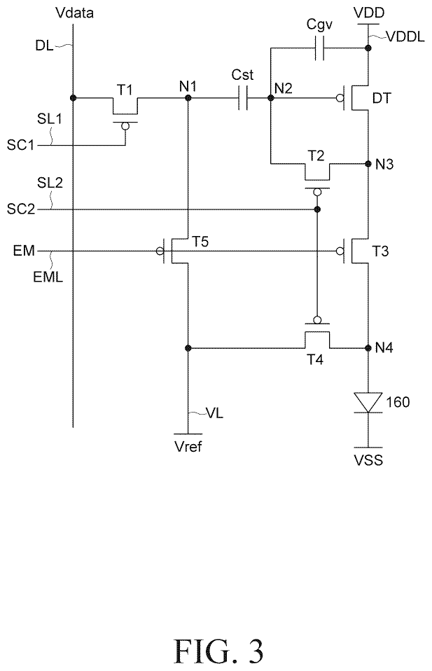

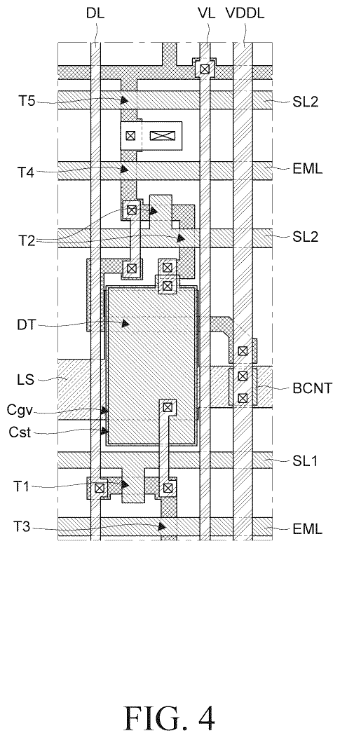

Hereinafter, a sub pixel of a display apparatus 100 according to an exemplary embodiment of the present disclosure will be described with reference to FIGS. 3 and 4.

FIG. 3 is a circuit diagram of a sub pixel of a display apparatus according to an exemplary embodiment of the present disclosure. FIG. 4 is a plan view of a sub pixel of a display apparatus according to an exemplary embodiment of the present disclosure. In FIG. 4, for the convenience of description, a light emitting diode 160 and a plurality of optical patterns 150 are not illustrated.

Referring to FIGS. 3 and 4, a sub pixel may include six transistors, one storage capacitor Cst, one auxiliary capacitor Cgv, and a light emitting diode 160.

For example, the sub pixel circuit may include a driving transistor DT, a first transistor T1, a second transistor T2, a third transistor T3, a fourth transistor T4, a fifth transistor T5, a storage capacitor Cst, an auxiliary capacitor Cgv, and a light emitting diode 160. A sub pixel circuit including six transistors, one storage capacitor, and an auxiliary capacitor may be referred to as a 6T2C circuit, but is not limited by the term. Even though in FIG. 3, it is described that the driving transistor DT, the first transistor T1, the second transistor T2, the third transistor T3, the fourth transistor T4, and the fifth transistor T5 are implemented by p-type transistors, the present disclosure is not limited thereto. In the case of the p-type transistor, a low level voltage of each driving signal may refer to a voltage which turns on transistors and a high level voltage of each driving signal may refer to a voltage which turns off the transistors.

Here, a first electrode or a second electrode of the transistor to be described below may refer to a source electrode or a drain electrode. However, the terms of the first electrode and the second electrode are terms for distinguishing the electrodes, but do not limit what corresponds to each electrode. Further, in each electrode, the first electrode may not refer to the same electrode.

The sub pixel circuit may be supplied with a high potential voltage VDD, a low potential voltage VSS, a reference voltage Vref, and a data voltage Vdata. The high potential voltage VDD, the low potential voltage VSS, and the reference voltage Vref may be DC voltages (or direct current voltages) and the data voltage Vdata may be an AC voltage (or an alternating current voltage), but are not limited thereto.

The sub pixel circuit may be connected to a high potential voltage line VDDL which supplies a high potential voltage VDD, a low potential voltage line which supplies a low potential voltage VDD, a reference voltage line VL which supplies a reference voltage Vref, and a data line DL which supplies a data voltage Vdata. The high potential voltage VDD may be referred to as a first voltage and the low potential voltage VSS may be referred to as a second voltage which is lower than the first voltage, but the present disclosure is not limited thereto.

The high potential voltage VDD may have a voltage value higher than the low potential voltage VSS and the reference voltage Vref. The low potential voltage VSS may be equal to or lower than the reference voltage Vref. The data voltage Vdata may have a voltage value in a specific range. For example, the data voltage Vdata may have a value between 0 to 10 V, but the present disclosure is not limited thereto.

The driving transistor DT is a transistor for driving the light emitting diode 160 and may control a driving current applied to the light emitting diode 160 depending on a source-gate voltage. A first electrode of the driving transistor DT may be connected to the high potential voltage line VDDL. A second electrode of the driving transistor DT may be connected to a third node N3. A gate electrode of the driving transistor DT may be connected to a second node N2. The driving transistor DT is turned on or turned off according to a voltage of the second node N2 and may supply the high potential voltage VDD which is supplied by the high potential voltage line VDDL to the third node N3 when it is turned on.

The first transistor T1 may supply a data voltage Vdata from the data line DL which supplies a data voltage Vdata to the first node N1. A first electrode of the first transistor T1 may be connected to the data line DL. A second electrode of the first transistor T1 may be connected to the first node N1. For example, the second electrode of the first transistor T1 may be connected to the storage capacitor Cst and may be connected to a first electrode of the fifth transistor T5.

A gate electrode of the first transistor T1 may be connected to a first scan line SL1 which supplies the first scan signal SC1. The first transistor T1 may be turned on or turned off according to the first scan signal SC1. When the first transistor T1 is turned on, the first node N1 and the data line DL may be connected. In this case, the data voltage Vdata may be supplied to the first node N1 through the data line DL.

The second transistor T2 may form diode connection of the gate electrode and the drain electrode of the driving transistor DT. A first electrode of the second transistor T2 may be connected to the second node N2. The first electrode of the second transistor T2 may be connected to the gate electrode of the driving transistor DT and the storage capacitor Cst. A second electrode of the second transistor T2 may be connected to the third node N3. The second electrode of the second transistor T2 may be connected to a first electrode of the third transistor T3 and the second electrode of the driving transistor DT.

A gate electrode of the second transistor T2 may be connected to a second scan line SL2 which supplies a second scan signal SC2. The second transistor T2 may be turned on or turned off according to the second scan signal SC2. The second transistor T2 is turned on to connect between the second node N2 and the third node N3.

As illustrated in FIG. 4, the second transistor T2 may include a plurality of sub transistors. In this case, the second transistor T2 may be referred to as a multi-transistor, a double transistor, or a dual transistor. Alternatively, the second transistor T2 may include a plurality of gate electrodes. In this case, the second transistor T2 may be referred to as a multi-gate transistor, a double gate transistor, or a dual gate transistor.

If the second transistor T2 includes a plurality of sub transistors or a plurality of gate electrodes, current leaked from the second transistor T2, for example, a leakage current between the second node N2 and the reference voltage line VL may be effectively reduced.

The third transistor T3 may form a current path between the driving transistor DT and the light emitting diode 160. The third transistor T3 may be connected between the third node N3 and a fourth node N4. A first electrode of the third transistor T3 may be connected to the third node N3. For example, the first electrode of the third transistor T3 may be connected to the second electrode of the second transistor T2 and the second electrode of the driving transistor DT. The second electrode of the third transistor T3 may be connected to the fourth node N4. For example, a second electrode of the third transistor T3 may be connected to a second electrode of the fourth transistor T4 and the light emitting diode 160.

The gate electrode of the third transistor T3 may be connected to an emission signal line EML which supplies the emission signal EM. The third transistor T3 may be turned on or turned off according to the emission signal EM supplied from the emission signal line EML. When the third transistor T3 is turned on, the third node N3 and the fourth node N4 are connected to form a current path between the driving transistor DT and the light emitting diode 160.

The fourth transistor T4 may apply the reference voltage Vref to the first electrode of the light emitting diode 160. The fourth transistor T4 may be connected to the reference voltage line VL which supplies the reference voltage Vref, the fifth transistor T5, and the fourth node N4. The first electrode of the fourth transistor T4 may be connected to the fifth transistor T5 and the reference voltage line VL. For example, the first electrode of the fourth transistor T4 may be connected to a second electrode of the fifth transistor T5 and the reference voltage line VL. A second electrode of the fourth transistor T4 may be connected to the fourth node N4. The second electrode of the fourth transistor T4 may be connected to the third transistor T3 and the light emitting diode 160. For example, the second electrode of the fourth transistor T4 may be connected to the second electrode of the third transistor T3 and the first electrode of the light emitting diode 160.

A gate electrode of the fourth transistor T4 may be connected to a second scan line SL2 which supplies a second scan signal SC2. The fourth transistor T4 may be turned on or turned off according to the second scan signal SC2 which is supplied through the second scan line SL2. When the fourth transistor T4 is turned on, the fourth transistor connects between the fourth node N4 and the reference voltage line VL to charge the fourth node N4 with the reference voltage Vref.

As described above, when the fourth node N4 is charged with the reference voltage Vref, even though the second transistor T2 is turned on, an effect of raising a voltage of an electrode connected to the fourth node N4 of the light emitting diode 160, for example, the first electrode, may be reduced. As the rising of the voltage of the first electrode is reduced, an initial peak phenomenon in which the voltage excessively rises during an initial period may be reduced. As the initial peak is reduced, the imbalanced luminance at the edge or the center of the display panel, for example, black floating phenomenon may be improved and the luminance uniformity may be improved.

The fifth transistor T5 may apply the reference voltage Vref to the first node N1. A first electrode of the fifth transistor T5 may be connected to the first node N1. For example, the first electrode of the fifth transistor T5 may be connected to the storage capacitor Cst and may be connected to the second electrode of the first transistor T1. A second electrode of the fifth transistor T5 may be connected to the fourth transistor T4 and the reference voltage line VL which supplies the reference voltage Vref. For example, the second electrode of the fifth transistor T5 may be connected to the first electrode of the fourth transistor T4 and the reference voltage line VL.

A gate electrode of the fifth transistor T5 may be connected to the emission signal line EML which supplies the emission signal EM. The fifth transistor T5 may be turned on or turned off according to the emission signal EM input through the emission signal line EML. When the fifth transistor T5 is turned on, the fifth transistor connects between the first node N1 and the reference voltage line VL to charge the first node N1 with the reference voltage Vref.

The light emitting diode 160 may be disposed between the fourth node N4 and the low potential voltage line to which the low potential voltage VSS is supplied. For example, the first electrode of the light emitting diode 160 may be connected to the fourth node N4 and the second electrode of the light emitting diode 160 may be connected to the low potential voltage line. The low potential voltage VSS may be lower than the high potential voltage VDD described above. For example, the voltage which is supplied through the low potential voltage line may include a ground voltage. The low potential voltage VSS and the high potential voltage VDD may be set in advance.

The storage capacitor Cst may be connected between the first node N1 and the second node N2. For example, a first capacitor electrode of the storage capacitor Cst may be connected to the second node N2 which is connected to the gate electrode of the driving transistor DT. A second capacitor electrode of the storage capacitor Cst may be connected to the first node N1 which is connected to the first transistor T1 and the fifth transistor T5.

The storage capacitor Cst may be a component which charges an electric energy (for example, charges or a data voltage) to maintain a constant voltage for one frame. For example, when the input of the data voltage Vdata through the first transistor T1 stops during the process of driving a sub pixel circuit, the storage capacitor Cst supplies a stored data voltage to the driving transistor DT to maintain the driving of the driving transistor DT for one frame.

The sub pixel circuit may further include an auxiliary capacitor Cgv. The auxiliary capacitor Cgv may be disposed between the first capacitor electrode of the storage capacitor Cst and the high potential voltage line VDDL which supplies the high potential voltage VDD. The auxiliary capacitor Cgv may suppress a voltage of the gate electrode of the driving transistor DT from rising due to the kick-back phenomenon.

In the meantime, in FIGS. 3 and 4, it is described that the driving circuit of the sub pixel SP of the display apparatus 100 according to the exemplary embodiment of the present disclosure has a 6T2C structure including six transistors, one storage capacitor Cst, and one auxiliary capacitor Cgv. However, the number and a connection relationship of the transistors and the capacitors may vary in various ways depending on the design and are not limited thereto.

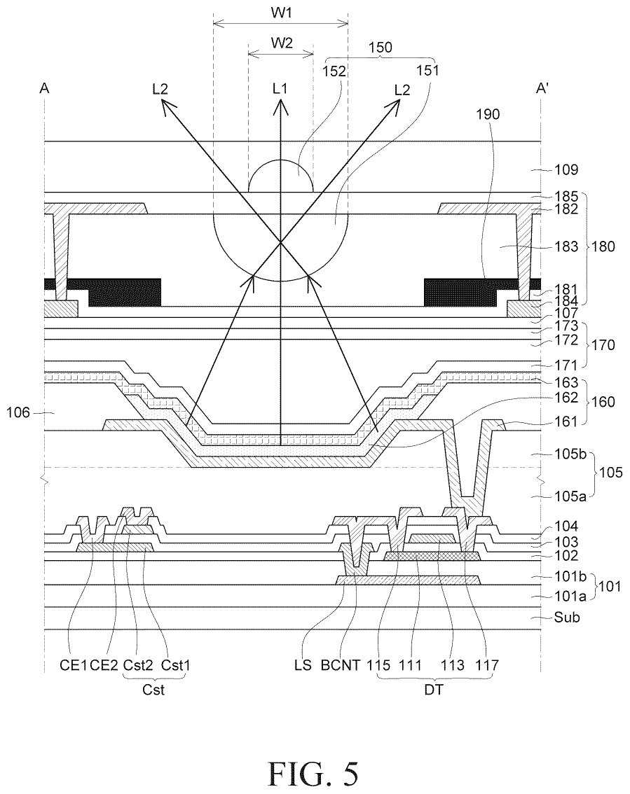

Hereinafter, a sub pixel of a display apparatus 100 according to an exemplary embodiment of the present disclosure will be described in detail with reference to FIG. 5.

FIG. 5 is a cross-sectional view taken along the line A-A′ of FIG. 2 according to one embodiment. FIG. 5 is a cross-sectional view for a first sub pixel SP1.

Referring to FIG. 5, in the display apparatus 100 according to the exemplary embodiment of the present disclosure, on a substrate Sub, a buffer layer 101, a gate insulating layer 102, a first interlayer insulating layer 103, a second interlayer insulating layer 104, a first over coating layer 105, a bank 106, a light shielding layer LS, an auxiliary electrode BCNT, a storage capacitor Cst, a first connection electrode CE1, a second connection electrode CE2, a driving transistor DT, a light emitting diode 160, an encapsulation unit 170, a touch sensing unit 180, a light shielding pattern 190, a second over coating layer 109, and a plurality of optical patterns 150 may be disposed.

The substrate Sub may include an insulating material. The substrate Sub may include a transparent material. For example, the substrate Sub may include glass or plastic.

The buffer layer 101 may be disposed on the substrate Sub. The buffer layer 101 may include a first buffer layer 101a and a second buffer layer 101b.

The first buffer layer 101a may be disposed on the substrate Sub. The first buffer layer 101a may reduce permeation of moisture or impurities through the substrate Sub. The first buffer layer 101a may include an inorganic insulating material, such as silicon oxide (SiOx) or silicon nitride (SiNx). The first buffer layer 101a may have a multi-layered structure. For example, the first buffer layer 101a may have a laminated structure of a film formed of silicon nitride (SiNx) and a film formed of silicon oxide (SiOx).

The light shielding layer LS may be disposed on the first buffer layer 101a. The light shielding layer LS is disposed so as to overlap at least the semiconductor layer 111 of the driving transistor DT to block light incident onto the semiconductor layer 111. In the meantime, even though in the drawing, it is illustrated that the light shielding layer LS is a single layer, the light shielding layer LS may be formed by a plurality of layers. The light shielding layer LS may be formed of various conductive materials, for example, magnesium (Mg), aluminum (Al), nickel (Ni), chrome (Cr), molybdenum (Mo), tungsten (W), gold (Au), or an alloy thereof.

The second buffer layer 101b may be disposed on the light shielding layer LS. Further, the second buffer layer 101b may protect the driving transistor DT from impurities such as alkali ions leaked from the substrate Sub. Further, the second buffer layer 101b may improve the adhesive strength between layers disposed above the second buffer layer 101b and the substrate Sub. Further, the second buffer layer 101b may include an inorganic insulating material, such as silicon oxide (SiOx) or silicon nitride (SiNx). The second buffer layer 101b may have a multi-layered structure. For example, the second buffer layer 101b may have a laminated structure of a film formed of silicon nitride (SiNx) and a film formed of silicon oxide (SiOx).

The driving transistor DT may be disposed on the buffer layer 101.

Referring to FIG. 5, the driving transistor DT may include a semiconductor layer 111, a gate electrode 113, a source electrode 115, and a drain electrode 117.

A patterned semiconductor layer 111 is disposed above the buffer layer 101.

The semiconductor layer 111 may be formed of oxide semiconductor material. In contrast, the semiconductor layer 111 may be formed of polycrystalline silicon and in this case, impurities may be doped on both edges of the semiconductor layer 111.

The gate insulating layer 102 which is formed of an insulating material may be disposed above the semiconductor layer 111. The gate insulating layer 102 may include an insulating material. For example, the gate insulating layer 102 may include an inorganic insulating material, such as silicon oxide (SiOx) or silicon nitride (SiNx). The gate insulating layer 102 may include a material having a high permittivity. For example, the gate insulating layer 102 may include a High-K material, such as hafnium oxide (HfO). The gate insulating layer 102 may have a multi-layered structure.

The gate insulating layer 102 may extend between the semiconductor layer 111 and the gate electrode 113 of the driving transistor DT.

In the meantime, in FIG. 5, it is illustrated that the gate insulating layer 102 is disposed on the entire surface of the substrate Sub, but the gate insulating layer 102 may be patterned to have the same shape as the gate electrode 113.

The gate electrode 113 which is formed of a conductive material, such as metal, is disposed above the gate insulating layer 102 so as to correspond to the semiconductor layer 111. Further, a gate line (not illustrated) may be disposed above the gate insulating layer 102. The gate line may extend along a row direction.

The gate electrode 113 may be formed of various conductive materials, for example, magnesium (Mg), aluminum (Al), nickel (Ni), chrome (Cr), molybdenum (Mo), tungsten (W), gold (Au), or an alloy thereof.

An auxiliary electrode BCNT is disposed above the gate insulating layer 102. The auxiliary electrode BCNT is an electrode for applying a voltage to the light shielding layer LS below the buffer layer 101. For example, the auxiliary electrode BCNT may be formed of the same material as the gate electrode 113 of the driving transistor DT. The auxiliary electrode BCNT may be formed of various conductive materials, for example, magnesium (Mg), aluminum (Al), nickel (Ni), chrome (Cr), molybdenum (Mo), tungsten (W), gold (Au), or an alloy thereof.

For example, the light shielding layer LS is electrically connected to another configuration disposed on the substrate Sub through the auxiliary electrode BCNT to be applied with a voltage. For example, referring to FIG. 4 together, the auxiliary electrode BCNT may be connected to the driving transistor DT and the high potential voltage line VDDL. Accordingly, the light shielding layer LS which is applied with a voltage through the auxiliary electrode BCNT does not operate as a floating gate and may minimize or at least reduce a fluctuation of a threshold voltage of the driving transistor DT which is generated by the floated light shielding layer LS.

The storage capacitor Cst including a first capacitor electrode Cst1 and a second capacitor electrode Cst2 is disposed above the gate insulating layer 102.

The first capacitor electrode Cst1 of the storage capacitor Cst may be disposed on the gate insulating layer 102. For example, the first capacitor electrode Cst1 may be formed of the same material as the gate electrode 113 of the driving transistor DT. The first capacitor electrode Cst1 may be formed of various conductive materials, for example, magnesium (Mg), aluminum (Al), nickel (Ni), chrome (Cr), molybdenum (Mo), tungsten (W), gold (Au), or an alloy thereof.

The first interlayer insulating layer 103 may be disposed on the gate electrode 113. The first interlayer insulating layer 103 may include an insulating material. For example, the first interlayer insulating layer 103 may include an inorganic insulating material, such as silicon oxide (SiOx) or Silicon Nitride (SiNx).

The first interlayer insulating layer 103 may be located on the gate insulating layer 102. The first interlayer insulating layer 103 may extend between the gate electrode 113 and the source electrode 115 of the driving transistor DT and between the gate electrode 113 and the drain electrode 117. For example, the source electrode 115 and the drain electrode 117 of the driving transistor DT may be insulated from the gate electrode 113 by the first interlayer insulating layer 103. The first interlayer insulating layer 103 may cover the gate electrode 113 of the driving transistor DT.

The second capacitor electrode Cst2 of the storage capacitor Cst may be disposed on the first interlayer insulating layer 103. The second capacitor electrode Cst2 may be disposed on the first interlayer insulating layer 103 so as to overlap the first capacitor electrode Cst1.

The second capacitor electrode Cst2 may be formed of various conductive materials, for example, magnesium (Mg), aluminum (Al), nickel (Ni), chrome (Cr), molybdenum (Mo), tungsten (W), gold (Au), or an alloy thereof.

The second interlayer insulating layer 104 may be disposed on the first interlayer insulating layer 103. In the second interlayer insulating layer 104, a contact hole for exposing the semiconductor layer 111 of the driving transistor DT, a contact hole for exposing the first capacitor electrode Cst1, a contact hole for exposing the second capacitor electrode Cst2, and a contact hole for exposing the auxiliary electrode BCNT may be formed. The second interlayer insulating layer 104 may be configured by a single layer of silicon nitride (SiNx) or silicon oxide (SiOx) or a multilayer thereof, but is not limited thereto.

The source electrode 115 and the drain electrode 117 may be located on the second interlayer insulating layer 104. The source electrode 115 and the drain electrode 117 may be formed of various conductive materials, for example, magnesium (Mg), aluminum (Al), nickel (Ni), chrome (Cr), molybdenum (Mo), tungsten (W), gold (Au), or an alloy thereof.

The source electrode 115 and the drain electrode 117 are in contact with the semiconductor layer 111 through the contact holes of the second interlayer insulating layer 104, the first interlayer insulating layer 103, and the gate insulating layer 102.

The drain electrode 117 of the driving transistor DT may be electrically connected to the anode electrode 161 of the light emitting diode 160 to be described below.

The first connection electrode CE1 may be located on the second interlayer insulating layer 104. The first connection electrode CE1 may be electrically connected to the first capacitor electrode Cst1 through contact holes of the second interlayer insulting layer 104 and the first interlayer insulating layer 103. For example, the first connection electrode CE1 may be electrically connected to another configuration disposed on the substrate Sub and may apply a voltage to the first capacitor electrode Cst1. The first connection electrode CE1 may be formed of various conductive materials, for example, magnesium (Mg), aluminum (Al), nickel (Ni), chrome (Cr), molybdenum (Mo), tungsten (W), gold (Au), or an alloy thereof.

The second connection electrode CE2 may be located on the second interlayer insulating layer 104. The second connection electrode CE2 may be electrically connected to the second capacitor electrode Cst2 through the contact hole of the second interlayer insulating layer 104. Further, the second connection electrode CE2 may be electrically connected to another configuration disposed on the substrate Sub and may apply a voltage to the second capacitor electrode Cst2. For example, the second connection electrode CE2 may also be electrically connected to the source electrode 115 or the drain electrode 117, but is not limited thereto. The second connection electrode CE2 may be formed of various conductive materials, for example, magnesium (Mg), aluminum (Al), nickel (Ni), chrome (Cr), molybdenum (Mo), tungsten (W), gold (Au), or an alloy thereof.

The first over coating layer 105 may be disposed above the driving transistor DT, the first connection electrode CE1, and the second connection electrode CE2. The first over coating layer 105 may include an insulating material. The first over coating layer 105 may include an organic insulating material. For example, the first over coating layer 105 may be formed of polyimide, acryl, or benzocyclobutene (BCB) resin, but it is not limited thereto.

The first over coating layer 105 includes a base portion 105a and a protruding portion 105b.

The base portion 105a and the protruding portion 105b may be integrally formed. For example, the base portion 105a and the protruding portion 105b are formed of the same material to be simultaneously formed by the same process, for example, by a mask process, but are not limited thereto.

The base portion 105a is disposed on the driving transistor DT. A top surface of the base portion 105a has a surface parallel to the substrate Sub. Therefore, the base portion 105a may protect the driving transistor DT and planarize the step of the layers disposed on the substrate Sub.

The protruding portion 105b is disposed on the base portion 105a. The protruding portion 105b is integrally formed with the base portion 105a to have a shape protruding from the base portion 105a. Therefore, the top surface of the protruding portion 105b may be disposed to be smaller than a bottom surface, but it is not limited thereto.

The protruding portion 105b has a top surface and a side surface. The top surface of the protruding portion 105b is a surface located on an uppermost portion of the protruding portion 105b and may be a surface parallel to the base portion 105a or the substrate Sub. The side surface of the protruding portion 105b may be a surface which connects the top surface of the protruding portion 105b and the base portion 105a. The side surface of the protruding portion 105b may be inclined toward the base portion 105a from the top surface of the protruding portion 105b.

In the present disclosure, it has been described that the first over coating layer 105 includes the base portion 105a having a flat top surface and the protruding portion 105b protruding from the base portion 105a. However, as long as the first over coating layer 105 is implemented by the base portion 105a and the protruding portion 105b, a detailed configuration of the first over coating layer 105 is not defined to the base portion 105a and the protruding portion 105b, but may be defined in various ways.

The light emitting diode 160 may be located on the first over coating layer 105. The light emitting diode 160 may cover the top surface of the base portion 105a and the side surface of the protruding portion 105b of the first over coating layer 105.

Referring to FIG. 5, the light emitting diode 160 may include an anode electrode 161, an emission structure 162, and a cathode electrode 163 which are sequentially laminated on the substrate Sub.

The anode electrode 161 is disposed on the first over coating layer 105 to cover the side surfaces and top surfaces of the base portion 105a and the protruding portion 105b. For example, the anode electrode 161 is disposed on the top surface of the base portion 105a where the protruding portion 105b is not disposed, the side surface and a partial area of the top surface of the protruding portion 105b and is disposed in accordance with the shapes of the base portion 105a and the protruding portion 105b. Accordingly, the anode electrode 161 may have a flat top surface on the top surface of the base portion 105a of the first over coating layer 105 and have an inclined top surface on the side surface of the protruding portion 105b.

The anode electrode 161 may include a conductive material. The anode electrode 161 may include a material having a high reflectance. For example, the anode electrode 161 may include a metal, such as aluminum (Al) and silver (Ag). The anode electrode 161 may have a multi-layered structure. For example, the anode electrode 161 may have a structure in which a reflective electrode formed of a metal is located between transparent electrodes formed of a transparent conductive material, such as indium tin oxide (ITO) and indium zinc oxide (IZO).

The anode electrode 161 of the light emitting diode 160 may be electrically connected to the drain electrode 117 (or the source electrode 115) of the driving transistor DT through a contact hole of the first over coating layer 105.

The bank 106 may be located between the anode electrodes 161 of adjacent sub pixels and disposed above the protruding portion 105b. The bank 106 may include an insulating material. For example, the bank 106 may include an organic insulating material. For example, the bank 106 may be formed of polyimide, acrylic, or benzocyclobutene (BCB) resin, and the bank 106 may include a material different from the first over coating layer 105.

The bank 106 may cover a part of the anode electrode 161 of the light emitting diode 160. For example, the bank 106 may cover an edge of the anode electrode 161.

The emission structure 162 is disposed on the anode electrode 161. The emission structure 162 may include an emission layer which emits specific color light. Therefore, the emission structure 162 disposed in the first sub pixel SP1 may be different from an emission structure disposed in the second sub pixel SP2 and an emission structure disposed in the third sub pixel SP3. In the meantime, the emission structure 162 may include at least one of an emission layer, a hole injection layer (HIL), a hole transport layer (HTL), an electron transport layer (ETL), and an electron injection layer (EIL). However, it is not limited thereto and the emission structure 162 may further include a common layer which is commonly disposed in the first sub pixel SP1, the second sub pixel SP2, and the third sub pixel SP3.

The emission structure 162 is disposed on the first over coating layer 105 so as to overlap the side surfaces and top surfaces of the base portion 105a and the protruding portion 105b. For example, the emission structure 162 is disposed so as to overlap the top surface of the base portion 105a where the protruding portion 105b is not disposed and the side surface of the protruding portion 105b. The emission structure 162 is disposed in accordance with the shape of the anode electrode 161 disposed on the base portion 105a and the protruding portion 105b. Accordingly, the emission structure 162 may have a flat top surface on the top surface of the base portion 105a of the first over coating layer 105 and have an inclined top surface on the side surface of the protruding portion 105b. Further, the emission structure 162 may also be disposed so as to overlap a part of the bank 106. For example, the emission structure 162 is disposed so as to overlap a lower side surface of the bank 106 and may have an inclined top surface along the lower side surface of the bank 106.

The cathode electrode 163 is disposed on the emission structure 162. The cathode electrode 163 may include a conductive material. A transmittance of the cathode electrode 163 may be higher than a transmittance of the anode electrode 161. For example, the cathode electrode 163 may be formed of a transparent conductive material, such as indium tin oxide (ITO) or indium zinc oxide (IZO). Accordingly, in the display apparatus 100 according to the exemplary embodiment of the present disclosure, light generated by the emission structure 162 may be emitted through the cathode electrode 163.

The cathode electrode 163 is disposed on the first over coating layer 105 and the bank 106 so as to overlap the side surfaces and top surfaces of the base portion 105a and the protruding portion 105b. For example, the cathode electrode 163 is disposed so as to overlap the top surface of the base portion 105a where the protruding portion 105b is not disposed and the side surface of the protruding portion 105b. The cathode electrode 163 is disposed in accordance with the shape of the emission structure 162 disposed on the base portion 105a and the protruding portion 105b. Further, the cathode electrode 163 is disposed so as to overlap the side surface of the bank 106 and may have an inclined top surface along the side surface of the bank 106 and extend to the top surface of the bank 106 to have a flat top surface.

The encapsulation unit 170 may be located on the light emitting diode 160. The encapsulation unit 170 may suppress the damage of the light emitting diodes 160 due to moisture and shocks from the outside.

The encapsulation unit 170 may have a multi-layered structure. For example, the encapsulation unit 170 may include a first encapsulation layer 171, a second encapsulation layer 172, and a third encapsulation layer 173 which are sequentially laminated, but the exemplary embodiments of the present disclosure are not limited thereto.

The first encapsulation layer 171 is disposed on the light emitting diode 160 to suppress the permeation of the moisture or oxygen. The first encapsulation layer 171 may be formed of an inorganic material, such as silicon oxide (SiOx), silicon nitride (SiNx), silicon oxy nitride (SiNxOy), or aluminum oxide (AlyOz), but is not limited thereto.

The second encapsulation layer 172 is disposed on the first encapsulation layer 171 to planarize the surface. Further, the second encapsulation layer 172 may cover foreign materials or particles which may be generated during a manufacturing process. The second encapsulation layer 172 may be formed of an organic material, such as silicon oxy carbon (SiOxCz), acryl or epoxy resin, but is not limited thereto.

The third encapsulation layer 173 is disposed on the second encapsulation layer 172 and may suppress the permeation of the moisture or oxygen, like the first encapsulation layer 171. At this time, the third encapsulation layer 173 and the first encapsulation layer 171 may be formed to seal the second encapsulation layer 172. Accordingly, the moisture or oxygen permeating the light emitting diode 160 may be effectively reduced by the third encapsulation layer 173. The third encapsulation layer 173 may be formed of an inorganic material, such as silicon oxide (SiOx), silicon nitride (SiNx), silicon oxy nitride (SiNxOy), or aluminum oxide (AlyOz), but is not limited thereto.

The inorganic buffer layer 107 may be disposed on the encapsulation unit 170. The inorganic buffer layer 107 may reduce inflow of impurities, such as alkali ions and improve an adhesive strength of the encapsulation unit 170 and the touch sensing unit 180 disposed above and below the inorganic buffer layer 107. The inorganic buffer layer 107 may include an inorganic insulating material, such as silicon oxide (SiOx) or silicon nitride (SiNx). Further, the inorganic buffer layer 107 has a laminated structure formed by a film formed of silicon nitride (SiNx) and silicon oxide (SiOx), but is not limited thereto.

The touch sensing unit 180 may be disposed on the inorganic buffer layer 107. The touch sensing unit 180 is disposed in the active area including the light emitting diode 160 to sense a touch input. The touch sensing unit 180 may sense external touch information using a finger of the user or a touch pen.

The touch sensing unit 180 includes an inorganic insulating layer 181, an organic layer 183, a bridge electrode 184, a touch electrode 182, and an organic insulating layer 185.

The bridge electrode 184 may be disposed on the inorganic buffer layer 107. The bridge electrode 184 may be a configuration which connects a disconnected touch electrode 182 at a point where a touch electrode 182 extending in the row direction and a touch electrode 182 extending in a column direction intersect each other.

A side surface of each of the touch electrodes 182 may be inclined with respect to the top surface of the organic layer 183. For example, the touch electrode 182 may be formed by patterning a metal layer formed on the top surface of the organic layer 183. Accordingly, a side portion of the touch electrode 182 may be formed to be inclined with respect to a top surface of the organic layer 183 during a process of patterning the metal layer.

The inorganic insulating layer 181 may be disposed on the bridge electrode 184. The inorganic insulating layer 181 may cover a top surface and a side surface of the bridge electrode 184. The inorganic insulating layer 181 may be formed of an inorganic material. For example, the inorganic insulating layer 181 may be formed of an inorganic material, such as silicon nitride (SiNx) and silicon oxy nitride (SiON), but is not limited thereto.

The light shielding pattern 190 is provided on the inorganic insulating layer 181. The light shielding pattern 190 may suppress color mixture which may be generated in an adjacent second sub pixel SP2 and an adjacent third sub pixel SP3 and performs reflection of external light.

The light shielding pattern 190 may be disposed so as to overlap the bridge electrode 184. The light shielding pattern 190 may be a black matrix and may be formed of black resin or chrome oxide.

The organic layer 183 may be disposed above the inorganic insulating layer 181 and the light shielding pattern 190. The organic layer 183 may ensure a gap between the light shielding pattern 190 and configurations disposed thereabove, for example, a gap between the light shielding pattern 190 and the bridge electrode 184 and the first optical pattern 151 and may be formed of an organic insulating material. For example, the organic layer 183 may be formed of photo acryl, benzocyclobutene (BCB), polyimide (PI), or polyamide (PA), but is not limited thereto.

In the meantime, the organic layer 183 may include a top surface concave toward a direction where the substrate Sub is located in an area which does not overlap the bridge electrode 184 and the touch electrode 182. For example, the top surface of the organic layer 183 may include a portion protruding toward a direction in which the substrate Sub is located along a bottom surface of the first optical pattern 151.

The first optical pattern 151 is disposed on the organic layer 183.

The first optical pattern 151 may be disposed so as to overlap the light emitting diode 160. For example, the first optical pattern 151 may overlap a top surface of the base portion 105a exposed by the protruding portion 105b.

The first optical pattern 151 may have a downwardly convex shape in a direction toward the substrate Sub. For example, the first optical pattern 151 may have a bottom surface corresponding to a concave top surface of the organic layer 183. For example, the first optical pattern 151 may have a bottom surface which protrudes toward a direction in which the substrate Sub is located.

The first optical pattern 151 may have a flat top surface. For example, a cross-sectional shape of the first optical pattern 151 may be a semi-circular shape. Therefore, the first optical pattern 151 may be referred to as a concave lens. However, the cross-sectional shape of the first optical pattern 151 may have various shapes, such as pyramid or cone without being limited thereto.

The first optical pattern 151 may be formed of a light transmitting material. For example, the first optical pattern 151 may be formed of a transparent organic insulating material.

The first optical pattern 151 may improve a side viewing angle of the light emitting diode 160. For example, light which is incident onto the bottom surface of the first optical pattern 151, among light emitted from the light emitting diode 160, is refracted from an interface of the organic layer 183 and the first optical pattern 151 to travel to a lateral direction. For example, referring to FIG. 5, it is confirmed that second light L2 emitted from the light emitting diode 160 is refracted from the interface of the organic layer 183 and the first optical pattern 151 so that an angle formed with a normal line of the substrate Sub is increased.

In the meantime, as illustrated in FIG. 5, the first optical pattern 151 may be disposed between adjacent touch electrodes 182, and the touch electrode 182 and the first optical pattern 151 may not overlap each other. Accordingly, light emitted from the light emitting diode 160 may be discharged through the first optical pattern 151.

Even though it is illustrated in FIG. 5 that one first optical pattern 151 is disposed in the first sub pixel SP1, the present disclosure is not limited thereto. For example, a plurality of first optical patterns 151 may be disposed in one first sub pixel SP1.

The touch electrode 182 may be disposed on the organic layer 183. The touch electrode 182 may be disposed to have a flat shape along the top surface of the organic layer 183. The touch electrode 182 may be disposed in a row direction and a column direction.

The organic insulating layer 185 may be disposed on the touch electrode 182. The organic insulating layer 185 may cover a top surface and a side surface of the touch electrode 182. Further, the organic insulating layer 185 may planarize an upper portion of the touch electrode 182.

The organic insulating layer 185 may be formed of an organic material. For example, the organic insulating layer 185 may be formed of photo acryl, benzocyclobutene (BCB), polyimide (PI), or polyamide (PA), but is not limited thereto.

Even though it is not illustrated in FIG. 5, in the non-active area, a routing line which connects a touch electrode 182 disposed at the outermost periphery of the active area to a touch pad disposed in the non-active area may be disposed.

Even though in FIG. 5, a touch on encapsulation (TOE) structure in which the touch sensing unit 180 is disposed above the display panel PN is illustrated, a structure of the touch sensing unit 180 according to the exemplary embodiment of the present disclosure is not limited thereto.

The second optical pattern 152 may be located on the touch sensing unit 180. The second optical pattern 152 may be disposed between the touch electrodes 182.

The second optical pattern 152 may be disposed so as to overlap a part of the first optical pattern 151. For example, the second optical pattern 152 may be disposed so as to overlap a center portion of the first optical pattern 151.

An area of the second optical pattern 152 which overlaps the substrate Sub may be smaller than an area of the first optical pattern 151 which overlaps the substrate Sub. For example, referring to FIG. 5, a width W2 of the second optical pattern 152 may be smaller than a width W1 of the first optical pattern 151.

The second optical pattern 152 may have a flat bottom surface. In contrast, a top surface of the second optical pattern 152 may be convex toward a direction in which the second over coating layer 109 is located. For example, a cross-sectional shape of the second optical pattern 152 may be a semi-circular shape. However, the cross-sectional shape of the second optical pattern 152 may have various shapes, such as pyramid or cone without being limited thereto. Therefore, the second optical pattern 152 may be referred to as a convex lens and/or convex pattern.

The second optical pattern 152 may be formed of a light transmitting material. For example, the second optical pattern 152 may be formed of a transparent organic insulating material.

The second optical pattern 152 may easily collect light emitted from the light emitting diode 160. For example, light which is incident onto the second optical pattern 152, among light emitted from the light emitting diode 160, is refracted from an interface of the second optical pattern 152 and the second over coating layer 109 to travel to a front direction. For example, first light L1 emitted from the light emitting diode 160 transmits the second optical pattern 152 to travel to a normal direction.

In the meantime, referring to FIG. 5, first light L1 may be light which transmits the first optical pattern 151. That is, the second optical pattern 152 may refract some of light which is refracted from the first optical pattern 151 to travel in the lateral direction to the front direction. Accordingly, the second optical pattern 152 may suppress the problem in that all light emitted from the first optical pattern 151 is refracted to the lateral direction so that the front luminance is reduced.

Even though it is illustrated in FIG. 5 that one second optical pattern 152 is disposed in the first sub pixel SP1, the present disclosure is not limited thereto. For example, a plurality of second optical patterns 152 may be disposed in one first sub pixel SP1.

The second over coating layer 109 may be disposed on the second optical pattern 152. The second over coat layer 109 may include an insulating material. The second over coating layer 109 may include an organic insulating material. For example, the second over coating layer 109 may be formed of polyimide, acryl, or benzocyclobutene (BCB) resin, but it is not limited thereto.

The second over coating layer 109 may planarize an upper portion of the second optical pattern 152. For example, the second over coating layer 109 may have a convex bottom surface corresponding to a top surface of the second optical pattern 152 and have a flat top surface.

In the meantime, even though in FIG. 5, only a cross-sectional view for the first sub pixel SP1 is illustrated, the second sub pixel SP2 and the third sub pixel SP3 may have the same structure as the first sub pixel SP1.

In the display apparatus 100 according to the exemplary embodiment of the present disclosure, the emission structure 162 and the cathode electrode 163 of the light emitting diode 160 are disposed so as to overlap the side surface of the protruding portion 105b of the first over coating layer 105. Therefore, the light emitting diode 160 may be disposed to be inclined with respect to the top surface of the base portion 105a and the top surface of the substrate Sub in an area which overlaps the side surface of the protruding portion 105b. The light emitting diode 160 may emit light from the protruding portion 105b having an inclined surface. Accordingly, as compared with an example that the light emitting diode 160 is disposed only on the base portion 105a having a flat top surface, light emitted from the light emitting diode 160 may easily travel to the lateral direction. Therefore, the display apparatus 100 according to the exemplary embodiment of the present disclosure includes the light emitting diode 160 having an inclined surface to improve a side viewing angle of each of the first sub pixel SP1, the second sub pixel SP2, and the third sub pixel SP3.

Further, in the display apparatus 100 according to the exemplary embodiment of the present disclosure, the first optical pattern 151 and the second optical pattern 152 which protrude in different directions are disposed above the light emitting diode 160 to simultaneously improve the front luminance and the side luminance. For example, the first optical pattern 151 may have a concave lens protruding toward the substrate Sub and the second optical pattern 152 may have a convex lens protruding toward the second over coating layer 109. Accordingly, light which is incident to the first optical pattern 151 is refracted to the lateral direction to travel. Therefore, light incident onto the first optical pattern 151 may improve a side luminance of the first sub pixel SP1, the second sub pixel SP2, and the third sub pixel SP3. In the meantime, light which is incident onto the second optical pattern 152, among light which is refracted from the first optical pattern 151 to travel, may be refracted from the interface of the second optical pattern 152 and the second over coating layer 109 toward the front direction. Accordingly, light which is incident onto the second optical pattern 152 in an area corresponding to the center portion of the first optical pattern 151 is focused in the front direction so that the front luminance may be improved. Accordingly, the second optical pattern 152 may suppress the problem in that all light emitted from the first optical pattern 151 is refracted to the lateral direction so that the front luminance is reduced. Accordingly, in the display apparatus 100, the front luminance and the side luminance are improved so that the driving voltage is lowered to reduce power consumption. Further, luminance and heat are reduced so that the lifespan of the light emitting diode 160 may be improved.

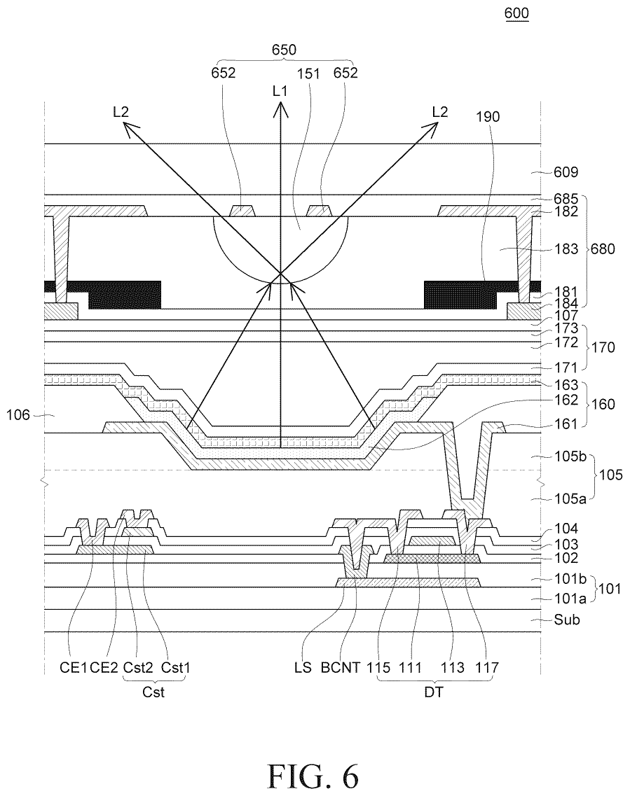

FIG. 6 is a cross-sectional view of a sub pixel of a display apparatus according to another exemplary embodiment of the present disclosure. A display apparatus 600 of FIG. 6 is different from the display apparatus 100 of FIGS. 1 to 5 for an organic insulating layer 685 of a touch sensing unit 680, a second optical pattern 652 of a plurality of optical patterns 650, and a second over coating layer 609, but the other configuration is substantially the same. Therefore, a redundant description will be omitted.

Referring to FIG. 6, the touch sensing unit 680 includes an inorganic insulating layer 181, an organic layer 183, a bridge electrode 184, a touch electrode 182, and an organic insulating layer 685.

The touch electrode 182 and a plurality of second optical patterns 652 of the plurality of optical patterns 650 are disposed on the bridge electrode 184, the inorganic insulating layer 181, and the organic layer 183.

A side surface of each of the plurality of second optical patterns 652 may be inclined with respect to the top surface of the organic layer 183. For example, the plurality of second optical patterns 652 may be formed by patterning a metal layer formed on the top surface of the organic layer 183. Accordingly, side portions of the plurality of second optical patterns 652 may be formed to be inclined with respect to a top surface of the organic layer 183 during a process of patterning the metal layer.

The plurality of second optical patterns 652 may be disposed so as to overlap the first optical pattern 151. One first optical pattern 151 may be disposed so as to overlap at least two or more second optical patterns 652. For example, the plurality of second optical patterns 652 may be disposed so as to correspond to the side portion of the first optical pattern 151. Accordingly, the center portion of the first optical pattern 151 may not overlap the plurality of second optical patterns 652.

Referring to FIG. 6, two second optical patterns 652 may be disposed on a portion excluding the center portion and both ends of one first optical pattern 151. Accordingly, both ends of the first optical pattern 151 may not overlap the plurality of second optical patterns 652.

The plurality of second optical patterns 652 may be formed of an opaque material. For example, the plurality of second optical patterns 652 may be formed of a metal material, such as aluminum (Al), and silver (Ag). The plurality of second optical patterns 652 may be formed on the same layer with the same material as the touch electrode 182, but is not limited thereto.

In the meantime, when the plurality of second optical patterns 652 are formed of an opaque material, the plurality of second optical patterns 652 may block light incident to the plurality of second optical patterns 652, among light emitted from the light emitting diode 160. For example, when the plurality of second optical patterns 652 are disposed so as to expose the center portion and both ends of the first optical pattern 151, the plurality of second optical patterns 652 may block all the light, excluding light which travels in an area corresponding to the center portion of the first optical pattern 151 and light which travels in an area corresponding to both ends of the first optical pattern 151. For example, referring to FIG. 6, the plurality of second optical patterns 652 allow only first light L1 traveling between a plurality of adjacent second optical patterns 652 and second light L2 traveling between the plurality of second optical patterns 652 and the touch electrode 182 to travel to the outside of the display apparatus 600.

The organic insulating layer 685 which covers a top surface and a side surface of each of the plurality of second optical patterns 652 and the touch electrode 182 may be disposed on the plurality of second optical patterns 652 and the touch electrode 182. The organic insulating layer 685 may planarize upper portions of the plurality of second optical patterns 652 and the touch electrode 182.

The second over coating layer 609 is disposed on the touch sensing unit 680. The second over coating layer 609 may be disposed along a flat top surface of the organic insulating layer 685.

In the display apparatus 600 according to another exemplary embodiment of the present disclosure, the emission structure 162 and the cathode electrode 163 of the light emitting diode 160 are disposed so as to overlap the side surface of the protruding portion 105b of the first over coating layer 105. Therefore, the light emitting diode 160 may be disposed so as to be inclined with respect to the top surface of the base portion 105a and the top surface of the substrate Sub in an area overlapping the side surface of the protruding portion 105b. Therefore, the side viewing angle of each of the first sub pixel SP1, the second sub pixel SP2, and the third sub pixel SP3 may be improved.

The display apparatus 600 according to another exemplary embodiment of the present disclosure includes the plurality of optical patterns 650 including a first optical pattern 151 and a second optical pattern 652 which protrude in different directions to improve the front luminance and easily control the side viewing angle. For example, in the display apparatus 600 according to another exemplary embodiment of the present disclosure, the first optical pattern 151 having a concave lens shape is disposed above the light emitting diode 160, thereby improving a side viewing angle of each of the first sub pixel SP1, the second sub pixel SP2, and the third sub pixel SP3. Further, in the display apparatus 600 according to another exemplary embodiment of the present disclosure, the second optical pattern 652 formed of an opaque material is disposed so as to overlap a partial area of the first optical pattern 151. Therefore, light which is incident onto the plurality of second optical patterns 652, among light emitted from the light emitting diode 160, may be blocked. Accordingly, when the plurality of second optical patterns 652 is disposed so as to correspond to both sides of each of the first sub pixel SP1, the second sub pixel SP2, and the third sub pixel SP3, in each of the first sub pixel SP1, the second sub pixel SP2, and the third sub pixel SP3, a viewing angle for a specific area may be blocked. When the display apparatus 600 is a stereoscopic image display apparatus, the plurality of second optical patterns 652 separates images of the left eye and the right eye, to suppress the crosstalk. Accordingly, the display apparatus 600 according to another exemplary embodiment of the present disclosure may easily control a viewing angle using the plurality of optical patterns 650 and improve an image quality.

Further, in the display apparatus 600 according to another exemplary embodiment of the present disclosure, the side surfaces of the plurality of second optical patterns 652 are inclined with respect to the top surface of the substrate Sub to improve the side viewing angle. For example, top surfaces of the plurality of second optical patterns 652 may be smaller than bottom surfaces of the plurality of second optical patterns 652. Accordingly, light emitted from each of the first sub pixel SP1, the second sub pixel SP2, and the third sub pixel SP3 may be emitted without restricting the viewing angle according to the inclined surfaces of the plurality of second optical patterns 652. For example, if the top surfaces of the plurality of second optical patterns 652 are equal to or larger than the bottom surfaces of the plurality of second optical patterns 652, light traveling at a smaller inclination angle with respect to the normal line of the substrate Sub may travel without being restricted by the bottom surfaces of the plurality of second optical patterns 652. However, light traveling at a larger inclination angle with respect to the normal line of the substrate Sub may be restricted by the top surfaces of the plurality of second optical patterns 652. Accordingly, in the display apparatus 600 according to another exemplary embodiment of the present disclosure, the side surfaces of the plurality of second optical patterns 652 include an inclined surface inclined with respect to the top surface of the substrate Sub to emit light traveling at a larger inclination angle with respect to the normal line of the substrate Sub. Accordingly, the side viewing angle may be improved in the display apparatus 600 according to another exemplary embodiment of the present disclosure.

Further, in the display apparatus 600 according to another exemplary embodiment of the present disclosure, the plurality of second optical patterns 652 are disposed on the same layer as the touch electrode 182 of the touch sensing unit 680. Therefore, the plurality of second optical patterns 652 may be formed by the same process as the touch electrode 182 of the touch sensing unit 680 and an additional manufacturing process for the plurality of second optical patterns 652 is not requested, thereby reducing the manufacturing cost or the process procedure. Further, in the display apparatus 600 according to another exemplary embodiment of the present disclosure, the plurality of second optical patterns 652 are formed together with the touch sensing unit 680 so that the thickness of the display apparatus 600 may be reduced.

The exemplary embodiments of the present disclosure can also be described as follows:

According to an embodiment of the present disclosure, there is provided a display apparatus. The display apparatus comprises a substrate including a sub pixel, a first over coating layer which is disposed on the substrate and includes a base portion and a protruding portion disposed on the base portion, a light emitting diode which is disposed in the sub pixel and covers a top surface of the base portion and a side surface of the protruding portion, a first optical pattern disposed on the light emitting diode, and a second optical pattern which is disposed on the first optical pattern and overlaps the first optical pattern, the first optical pattern and the second optical pattern protruding in different directions, wherein the side surface of the protruding portion forms an inclined surface with respect to the top surface of the base portion

The first optical pattern may overlap the top surface of the base portion exposed by the protruding portion.

The first optical pattern may protrude to a direction in which a bottom surface of the display apparatus is located, and the second optical pattern may protrude to a direction in which a top surface of the display apparatus is located.

An area of the second optical pattern which overlaps the substrate may be smaller than an area of the first optical pattern which overlaps the substrate.

The display apparatus may further comprise a touch sensing unit disposed on the light emitting diode, wherein the touch sensing unit may include a bridge electrode, an inorganic insulating layer, an organic layer, a touch electrode, and an organic insulating layer which are sequentially laminated on the light emitting diode, and the first optical pattern may be disposed on the organic layer, so that a top surface of the organic layer may include a portion protruding toward a direction in which the substrate is located along a bottom surface of the first optical pattern.

The display apparatus may further comprise a second over coating layer disposed on the second optical pattern, wherein the bottom surface of the first optical pattern may protrude in the direction in which the substrate is located and a top surface of the second optical pattern may protrude in a direction in which the second over coating layer is located.

The second optical pattern may be formed of a light transmitting material.

A center of the second optical pattern and a center of the first optical pattern may correspond to each other.

The second optical pattern may be disposed on the same layer as the touch electrode.

The second optical pattern may be formed of an opaque material.

The second optical pattern may be formed on the same layer with the same material as the touch electrode.

A side surface of the second optical pattern may be inclined with respect to a top surface of the substrate.

The second optical pattern may be provided in plural and disposed on a portion excluding a center portion and both ends of of the first optical pattern.

The first optical pattern and the second optical pattern may be disposed in a center portion of the sub pixel.

The first optical pattern may be formed of a light transmitting material.

The base portion and the protruding portion may be integrally formed.

The first optical pattern may have a flat top surface, and the second optical pattern may have a flat bottom surface.

The display apparatus may further comprise a bank disposed above the protruding portion of the first over coating layer, wherein the light emitting diode may be disposed so as to overlap a part of the bank.

According to another aspect of the present disclosure, there is provided a display apparatus. The display apparatus comprises a substrate including a sub pixel, an over coating layer which is disposed on the substrate and includes a base portion and a protruding portion disposed on the base portion, a light emitting diode which is disposed in the sub pixel and covers a top surface of the base portion and a side surface of the protruding portion, a concave lens disposed above the light emitting diode, and a convex patterns which overlaps the concave lens on the concave lens.

The display apparatus may further comprise a touch sensing unit disposed on the light emitting diode, wherein the touch sensing unit may include a bridge electrode, an inorganic insulating layer, an organic layer, a touch electrode, and an organic insulating layer which are sequentially laminated on the light emitting diode, and the concave lens may be disposed between adjacent touch electrodes.

The convex pattern may be disposed on the touch sensing unit.

The convex pattern may be formed of a light transmitting material.

The convex pattern may overlap a center portion of the concave lens and an edge of the concave lens may not overlap the convex pattern.

The convex pattern may be disposed on the same layer as the touch electrode.

The convex pattern may be formed of an opaque material.

Two or more convex patterns, may be disposed on one concave lens.

The two or more convex patterns may not overlap a center portion of the one concave lens.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display apparatus, comprising:
a substrate including a sub pixel;
a first over coating layer on the substrate, the first over coating layer including a base portion and a protruding portion on the base portion;
a light emitting diode in the sub pixel, the light emitting diode covering a top surface of the base portion and a side surface of the protruding portion;
a first optical pattern on the light emitting diode; and
a second optical pattern on the first optical pattern and overlapping the first optical pattern, the first optical pattern and the second optical pattern protruding in different directions,
wherein the side surface of the protruding portion forms an inclined surface with respect to the top surface of the base portion.

2. The display apparatus according to claim 1, wherein the first optical pattern overlaps the top surface of the base portion exposed by the protruding portion.

3. The display apparatus according to claim 1, wherein the first optical pattern protrudes in a direction in which a bottom surface of the display apparatus is located, and the second optical pattern protrudes in a direction in which a top surface of the display apparatus is located.

4. The display apparatus according to claim 3, wherein an area of the second optical pattern which overlaps the substrate is smaller than an area of the first optical pattern which overlaps the substrate.

5. The display apparatus according to claim 1, further comprising:
a touch sensing unit on the light emitting diode, the touch sensing unit including a bridge electrode, an inorganic insulating layer, an organic layer, a touch electrode, and an organic insulating layer which are sequentially laminated on the light emitting diode,
wherein the first optical pattern is on the organic layer such that a top surface of the organic layer includes a portion protruding toward a direction in which the substrate is located along a bottom surface of the first optical pattern.

6. The display apparatus according to claim 5, further comprising:
a second over coating layer on the second optical pattern,
wherein the bottom surface of the first optical pattern protrudes in the direction in which the substrate is located and a top surface of the second optical pattern protrudes in a direction in which the second over coating layer is located.

7. The display apparatus according to claim 5, wherein the second optical pattern includes a light transmitting material.

8. The display apparatus according to claim 7, wherein a center of the second optical pattern and a center of the first optical pattern correspond to each other.

9. The display apparatus according to claim 5, wherein the second optical pattern is on a same layer as the touch electrode.

10. The display apparatus according to claim 5, wherein the second optical pattern includes an opaque material.

11. The display apparatus according to claim 10, wherein the second optical pattern is on a same layer and has a same material as the touch electrode.

12. The display apparatus according to claim 10, wherein a side surface of the second optical pattern is inclined with respect to a top surface of the substrate.

13. The display apparatus according to claim 10, wherein the second optical pattern is provided in plural and are on a portion excluding a center portion and both ends of the first optical pattern.

14. The display apparatus according to claim 1, wherein the first optical pattern and the second optical pattern are in a center portion of the sub pixel.

15. The display apparatus according to claim 1, wherein the first optical pattern includes a light transmitting material.

16. The display apparatus according to claim 1, wherein the base portion and the protruding portion are integrally formed.

17. The display apparatus according to claim 3, wherein the first optical pattern has a flat top surface and the second optical pattern has a flat bottom surface.

18. The display apparatus according to claim 1, further comprising:
a bank above the protruding portion of the first over coating layer,
wherein the light emitting diode overlaps a part of the bank.

19. A display apparatus, comprising:
a substrate including a sub pixel;
an over coating layer on the substrate, the over coating layer including a base portion and a protruding portion on the base portion;
a light emitting diode in the sub pixel, the light emitting diode covering a top surface of the base portion and a side surface of the protruding portion;
a concave lens above the light emitting diode; and
a convex pattern that overlaps the concave lens and on the concave lens.

20. The display apparatus according to claim 19, further comprising:
a touch sensing unit on the light emitting diode, the touch sensing unit including a bridge electrode, an inorganic insulating layer, an organic layer, a touch electrode, and an organic insulating layer which are sequentially laminated on the light emitting diode, and the concave lens is between adjacent touch electrodes.

21. The display apparatus according to claim 20, wherein the convex pattern is on the touch sensing unit.

22. The display apparatus according to claim 21, wherein the convex pattern includes a light transmitting material.

23. The display apparatus according to claim 22, wherein the convex pattern overlaps a center portion of the concave lens and an edge of the concave lens is non-overlapping with the convex pattern.

24. The display apparatus according to claim 20, wherein the convex pattern is on a same layer as the touch electrode.

25. The display apparatus according to claim 24, wherein the convex pattern includes an opaque material.

26. The display apparatus according to claim 25, wherein two or more convex patterns are disposed on one concave lens.

27. The display apparatus according to claim 26, wherein the two or more convex patterns are non-overlapping with a center portion of the one concave lens.
